(19) United States
(12) Patent Application Publication
(10) Pub. No.: US 2010/0301486 A1
(43) Pub. Date: Dec. 2, 2010

(54) HIGH-ASPECT RATIO CONTACT ELEMENT WITH SUPERIOR SHAPE IN A SEMICONDUCTOR DEVICE FOR IMPROVING LINER DEPOSITION

(76) Inventors: Kai Frohberg, Niederau (DE); Frank Feustel, Dresden (DE); Thomas Werner, Moritzburg (DE)

Correspondence Address: WILLIAMS, MORGAN & AMERSON, 10333 RICHMOND, SUITE 1100, HOUSTON, TX, 77042, US

(21) Appl. No.: 12/785,726

(22) Filed: May 24, 2010

(30) Foreign Application Priority Data
May 29, 2009 (DE) 10 2009 023 251.6

(51) Int. Cl. H01L 23/48; H01L 21/768

(52) U.S. Cl. 257/770; 438/668; 257/774; 257/E21.585; 257/E23.011

(57) ABSTRACT

Contact elements of sophisticated semiconductor devices may be formed by lithographical patterning, providing a spacer element for defining the final critical width in combination with increasing a width of the contact opening prior to depositing the spacer material. The width may be increased, for instance by ion sputtering, thereby resulting in superior process conditions during the deposition of a contact metal. As a result, the probability of generating contact failures for contact elements having critical dimensions of approximately 50 nm and less may be significantly reduced.

### BACKGROUND OF THE INVENTION

1. Field of the Invention

The present disclosure generally relates to the field of semiconductor manufacturing, and, more particularly, to the formation of an interconnect structure directly connecting to a circuit element.

2. Description of the Related Art

Semiconductor devices, such as advanced integrated circuits, typically contain a great number of circuit elements, such as transistors, capacitors, resistors and the like, which are usually formed in a substantially planar configuration on an appropriate substrate having formed thereon a semiconductor layer. Due to the large number of circuit elements and the required complex layout of modern integrated circuits, the electrical connections of the individual circuit elements may generally not be established within the same level on which the circuit elements are manufactured, but require a plurality of additional “wiring” layers, which are also referred to as metallization layers. These metallization layers generally include metal-containing lines, providing the inner-level electrical connection, and also include a plurality of inter-level connections, which are also referred to as “vias,” that are filled with an appropriate metal and provide the electrical connection between two neighboring stacked metallization layers.

Due to the continuous reduction of the feature sizes of circuit elements in modern integrated circuits, the number of circuit elements for a given chip area, that is, the packing density, also increases, thereby requiring an over-proportional increase in the number of electrical connections to provide the desired circuit functionality. Therefore, the number of stacked metallization layers usually increases as the number of circuit elements per chip area becomes larger, while nevertheless the sizes of individual metal lines and vias are reduced.

Similarly, the contact structure of the semiconductor device, which may be considered as an interface connecting the circuit elements of the device level with the metallization system, has to be adapted to the reduced feature sizes in the device level and the metallization system. For this reason, very sophisticated patterning strategies may have to be applied in order to provide the contact elements with the required density and with appropriate reduced dimensions, at least at the device level side, in order to appropriately connect to the contact regions, such as drain and source regions, gate electrode structures and the like, without contributing to pronounced leakage current paths and even short circuits and the like. In many conventional approaches, the contact elements or contact plugs are typically formed by using a tungsten-based metal in an interlayer dielectric stack that is typically comprised of silicon dioxide in combination with an etch stop material, such as a silicon nitride material. Due to the very reduced critical dimensions of the circuit elements, such as the transistors, the respective contact elements have to be formed on the basis of contact openings with an aspect ratio which may be as high as approximately 8:1 or more, wherein a diameter of the contact openings may be 0.1 μm or significantly less for transistor devices of, for instance, the 65 nm technology node. In even further sophisticated approaches, and in very densely packed device regions, the width of the contact openings may be 50 nm and less. Generally, an aspect ratio of such contact openings may be defined as the ratio of the depth of the opening relative to the width of the opening.

Hence, after providing the contact opening with the required minimum width, an appropriate conductive material, such as tungsten, in combination with an appropriate barrier layer system has to be deposited, which may typically be accomplished on the basis of sputter deposition techniques, for instance, for the barrier materials and CVD (chemical vapor deposition)-like process recipes for forming the tungsten material. During the deposition process, the high aspect ratio of the contact openings may provide very sophisticated deposition conditions in order to obtain a substantially void-free incorporation of the tungsten material in the contact openings, since otherwise a significantly increased overall contact resistance may be caused. Thus, upon further reducing the critical dimension of the contact elements, respective etch masks may have to be provided on the basis of an appropriate resist material that is to be patterned by using sophisticated lithography techniques. Due to the high aspect ratio of the opening to be formed in the interlayer dielectric material, the patterning of the etch mask and the interlayer dielectric material may require additional strategies for finally adjusting the desired critical dimension of the contact openings. In some approaches, the final critical dimension may be adjusted by performing a lithography process and a patterning strategy in order to obtain a basic contact opening, which may be subsequently coated with a dielectric liner material in order to reduce the effective width of the opening. Although this approach is very promising in further reducing the critical width of contact elements for given lithography capabilities, additional problems may be involved upon further reducing the desired critical width, as will be explained with reference to FIGS. 1a-1d in more detail.

FIG. 1a schematically illustrates a cross-sectional view of a semiconductor device 100 comprising a substrate 101, such as a silicon substrate or any other appropriate carrier material, in order to provide thereabove a semiconductor layer 102, such as a silicon layer and the like. The semiconductor layer 102 may comprise a plurality of semiconductor regions and isolation areas (not shown) in order to appropriately laterally delineate circuit elements and device areas from each other. For convenience, in the example shown, the semiconductor layer 102 may represent a semiconductor region in and above which a plurality of circuit elements 110 are formed, such as field effect transistors and the like. The semiconductor layer 102 in combination with the circuit elements formed therein and thereabove may also be referred to as a device level 110, which thus represents semiconductor-based circuit features, wherein transistors of any type and configuration typically represent the dominant circuit element. For example, the circuit elements 110 may comprise a gate electrode structure 111 formed on the semiconductor region 102, which in turn comprises drain and source areas 112 in accordance with the device requirements so as to achieve the desired electrical behavior in the device level 110. As previously explained, in sophisticated applications, critical dimensions of the circuit elements 110 may be approximately 50 nm and less, for instance a gate length of the gate electrode structure 111 may be 50 nm and less, thereby also requiring similar critical dimensions of contact elements 123, which are to be formed in a contact level 120 of the device 100. The circuit elements 110 typically comprise appropriate contact regions 113 which may be specifically designed in view of a reduced overall contact resistivity. Frequently, the conductivity of the contact regions 113 is increased by providing a metal silicide, such as a nickel silicide, cobalt silicide, platinum silicide and the like.

The contact level 120 typically comprises an interlayer dielectric material 122, such as a silicon dioxide material, in combination with an etch stop layer 121, such as a silicon nitride material.

The semiconductor device 100 as illustrated in FIG. 1a is typically formed on the basis of well-established process techniques. For example, after defining appropriate semiconductor regions in the layer 102, which may be accomplished by providing isolation structures such as shallow trench isolations and the like, the circuit elements of the device level 110 may be provided, for instance, in the form of the gate electrode structures 111 and the drain and source regions 112 by applying material deposition techniques, sophisticated lithography and patterning processes, ion implantation processes and the like, as is required for obtaining the desired circuit characteristics. After the complex manufacturing sequence for forming circuit elements in the device level 110, the contact level 120 may be formed by depositing the etch stop material 121, which is typically accomplished by using plasma enhanced CVD techniques, in which process parameters may be readily adjusted so as to achieve the desired etch stop characteristics and other material characteristics, such as internal stress level and the like, in accordance with the device requirements. Thereafter, the interlayer dielectric material 122 may be deposited, for instance, on the basis of tetra methyl orthosilicate (TEOS) or any other appropriate precursor material for depositing a silicon dioxide material. Thereafter, a planarization of the resulting surface topography is typically applied in view of superior conditions for a subsequent patterning process for forming contact openings in the materials 122 and 121.

FIG. 1b schematically illustrates a cross-sectional view of the device 100 in a further advanced manufacturing stage. As illustrated, a contact opening 122A is formed in the interlayer dielectric material 122 wherein, for convenience, the outermost contact element 123 of FIG. 1a is illustrated only. As discussed above, the overall reduced feature sizes in the device level 110 may require a correspondingly increased density of contact elements in the contact level 120, which may thus require appropriate critical dimensions for the contact opening 122A. For this purpose, the opening 122A may be formed on the basis of sophisticated lithography and anisotropic etch techniques in which an etch mask, such as a resist mask, may be provided, possibly in addition to other materials such as anti-reflective coating (ARC) materials and the like, in order to provide a resist mask having a sufficient thickness for patterning the interlayer dielectric material 122. Based on the etch mask, an anisotropic etch process may be performed by using any appropriate etch chemistry in a plasma ambient in order to remove silicon dioxide material selectively to the etch stop material 121. Since the opening 122A may have a high aspect ratio, that is, the thickness of interlayer dielectric material 122 may be several hundred nanometers, while a width 122W of the opening 122A may be 50 nm and less, an appropriate patterning strategy is applied so as to reliably pattern the opening 122A, wherein the finally required critical width of the contact opening 122A may be adjusted on the basis of a subsequent deposition and etch sequence.

FIG. 1c schematically illustrates the semiconductor device 100 in a further advanced stage in which a spacer layer or liner 124 is formed on exposed surface areas of the device 100. The liner 124 is typically provided in the form of a silicon dioxide material using any appropriate deposition technique, such as plasma enhanced CVD and the like, with an appropriate thickness 124T, based on which the desired final critical width of the opening 122A may be adjusted. During the deposition of the liner 124, the pronounced surface topography caused by the high aspect ratio of the contact opening 122A may, however, result in a significant “overgrowth” of material at corner areas 122C of the contact opening 122A in order to provide the required layer thickness of the material 124 within the contact opening 122A.

FIG. 1d schematically illustrates the semiconductor device 100 with spacer elements or a liner material 124A formed within the contact opening 122A, which is accomplished by performing an anisotropic etch process, for instance on the basis of similar process parameters as used during the previous etch process for forming the contact opening 122A. During this etch process, the spacer material 124 (FIG. 1c) is substantially completely removed from the horizontal surface areas of the dielectric material 122 and may also significantly reduce a thickness of the material 124 at a bottom of the contact opening 122A. Consequently, after the etch process, a desired critical width 122R may be obtained in the contact opening 122A, at least in a bottom portion 122L thereof without requiring sophisticated lithography techniques. However, as previously explained, the increased overhangs at the corner portion 122C may result in a narrowing of an upper portion 122U, which may have a significant influence on the further processing. That is, in a further etch step, it may be etched through the etch stop layer 121 on the basis of the contact opening 122A having the reduced critical width 122R. Thereafter, a conductive barrier material, such as titanium in combination with titanium nitride, is typically deposited by using sophisticated sputter deposition techniques, wherein the pronounced reduction in width of the upper portion 122U may result in extremely challenging deposition conditions, which in turn may cause a further narrowing of the upper portion 122U. Consequently, during the subsequent deposition process for providing the actual contact metal, such as tungsten, a reliable fill of the contact opening 122A may be difficult to achieve, while in some cases even a complete closure of the upper portion 122U may be caused, thereby contributing to a severe contact failure in the level 120. Consequently, upon applying the conventional strategy as described above, the per se advantageous concept of adjusting the final critical width on the basis of a deposition and etch process may suffer from increased yield losses due to an increased contact resistivity and/or a high probability of creating total contact failures.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides semiconductor devices and manufacturing techniques in which the critical width of contact elements may be adjusted on the basis of a spacer element while significantly reducing the probability of creating contact failures caused by undue material accumulation at corners of the contact opening during the deposition of the spacer layer. To this end, the configuration of the contact opening may be appropriately modified at an upper portion thereof, substantially without affecting the bottom portion thereof, so as to provide a desired initial width at the bottom for a subsequent adjustment of the final desired critical width, while the deposition conditions may be significantly relaxed at the upper portion of the contact opening. The desired configuration may be accomplished in some illustrative aspects disclosed herein by increasing the width of the upper portion in a well-controllable manner, for instance prior to depositing the spacer material, thereby avoiding an undue creating of overhangs. In other illustrative aspects disclosed herein, the effective aspect ratio of the contact opening may be significantly reduced when forming the spacer material, thereby obtaining significantly less critical deposition conditions for forming the spacer elements, which may subsequently be used for producing the contact opening so as to have the required aspect ratio. Consequently, the concept of adjusting the critical width of contact openings may be extended to further reduced overall device dimensions while not unduly contributing to increased yield losses, as may typically result from conventional process techniques.

One illustrative method disclosed herein relates to forming a contact element of a semiconductor device. The method comprises forming a contact opening in an interlayer dielectric material that is formed above a semiconductor region, which in turn comprises a contact region. The method further comprises increasing a width of the contact opening at a top area thereof. Moreover, a spacer element is formed in the contact opening and an etch process is performed through the contact opening so as to etch through an etch stop layer that is formed between the semiconductor region and the interlayer dielectric material. Additionally, the method comprises filling the contact opening with a conductive material so as to form the contact element that connects to the contact region.

A further illustrative method disclosed herein relates to forming a contact element of a semiconductor device. The method comprises forming an etch mask above an interlayer dielectric material, wherein the etch mask comprises a hard mask material. Additionally, a first portion of a contact opening is formed in the interlayer dielectric material on the basis of the etch mask, wherein the first portion terminates in the interlayer dielectric material. The method further comprises forming a spacer element in the first portion and forming a second portion of the contact opening on the basis of the spacer element and at least the hard mask material. Furthermore, the method comprises performing an etch process so as to etch through an etch stop layer that is formed below the interlayer dielectric material, and filling the contact opening with a conductive material.

One illustrative semiconductor device disclosed herein comprises a contact region formed in a semiconductor region and an etch stop layer formed on a portion of the contact region. Moreover, an interlayer dielectric material is formed above the etch stop layer. The semiconductor device further comprises a contact element formed in the interlayer dielectric material and the etch stop layer so as to connect to the contact region, wherein the contact element comprises a tapered upper portion and a substantially non-tapered lower portion that are filled with a conductive material. Additionally, a spacer element is selectively formed on sidewalls of the lower portion of the contact element.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1d schematically illustrate cross-sectional views of a conventional semiconductor device during various manufacturing stages in forming sophisticated contact elements by adjusting the critical width on the basis of a spacer element according to conventional strategies;

FIGS. 2a-2f schematically illustrate cross-sectional views of a semiconductor device during various manufacturing stages in forming a sophisticated contact element by using a spacer element that may be formed on the basis of less critical process conditions by rounding corner areas of an upper portion of the contact opening, according to illustrative embodiments;

FIGS. 2g-2i schematically illustrate cross-sectional views of the semiconductor device according to illustrative embodiments in which an upper portion of a contact opening may be broadened during an etch process by eroding material of an etch mask, according to further illustrative embodiments; and

FIGS. 2j-2n schematically illustrate cross-sectional views of the semiconductor device during various manufacturing stages according to still further illustrative embodiments in which a spacer element of a contact opening may be formed on the basis of a significantly reduced aspect ratio.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The principles disclosed herein generally contemplate a manufacturing sequence and corresponding semiconductor devices in which an upper portion of a contact opening may be rounded or broadened at an appropriate phase during the patterning sequence, i.e., prior to the deposition of a spacer liner, thereby avoiding or at least significantly reducing the degree of narrowing of the contact opening in an upper portion thereof, so that the deposition conditions of a subsequent process sequence for filling in a conductive material may also be significantly relaxed while nevertheless obtaining a desired reduced critical width of the contact opening at the bottom portion thereof. For this purpose, in some illustrative embodiments, an appropriate material erosion process may be performed after patterning the contact opening in an interlayer dielectric material in order to preferably modify the upper portion of the contact opening. That is, the semiconductor device may be exposed to an appropriate reactive process ambient so as to increase a width at the top of the contact opening without significantly affecting the width at the bottom of the contact opening. In some illustrative embodiments, a particle bombardment, for instance in the form of an ion sputter process, may be applied to achieve a pronounced “corner rounding” at the upper portion of the contact opening, which may thus result in superior deposition conditions for the deposition of a spacer layer, which may subsequently be patterned into appropriate spacer elements for adjusting the desired critical width at the bottom of the contact opening. Hence, a very efficient process sequence may be established in which the capabilities of conventional concepts may be significantly extended due to the superior deposition conditions when forming the spacer elements, which in turn may result in superior deposition conditions during the filling in of the conductive contact metal.

In other illustrative embodiments, a desired degree of modification of an upper portion of the contact opening may be accomplished by modifying an etch mask at least once during the patterning sequence, for instance by intentionally initiating a material erosion of the etch mask so that, during the subsequent phase of the anisotropic etch process, a certain degree of “tapering” may be achieved in the upper portion of the resulting contact opening. Also, in this case, superior deposition conditions may be achieved, while also providing enhanced integrity of the remaining interlayer dielectric material.

In still other illustrative embodiments disclosed herein, the aspect ratio of the contact opening may be effectively reduced in view of the deposition of the spacer material, which may be accomplished by forming a first portion of the contact opening and depositing the spacer material on the basis of this first portion having a significantly reduced aspect ratio. Thereafter, appropriate spacers may be formed, which may be used during the further etch process and which may be consumed during the etch process, while nevertheless providing an efficient etch mask for obtaining the desired reduced critical width at the bottom of the contact opening at the end of the patterning process. In some illustrative embodiments, at least the second part of the patterning process may be performed on the basis of a hard mask material, thereby providing well-defined dimensions at the upper portion of the resulting contact opening, while at the same time obtaining the desired critical dimension at the bottom thereof. For example, the corresponding hard mask material may be removed upon etching through the etch stop layer, thereby substantially not contributing to additional process complexity while nevertheless providing superior reliability and performance of the resulting contact elements.

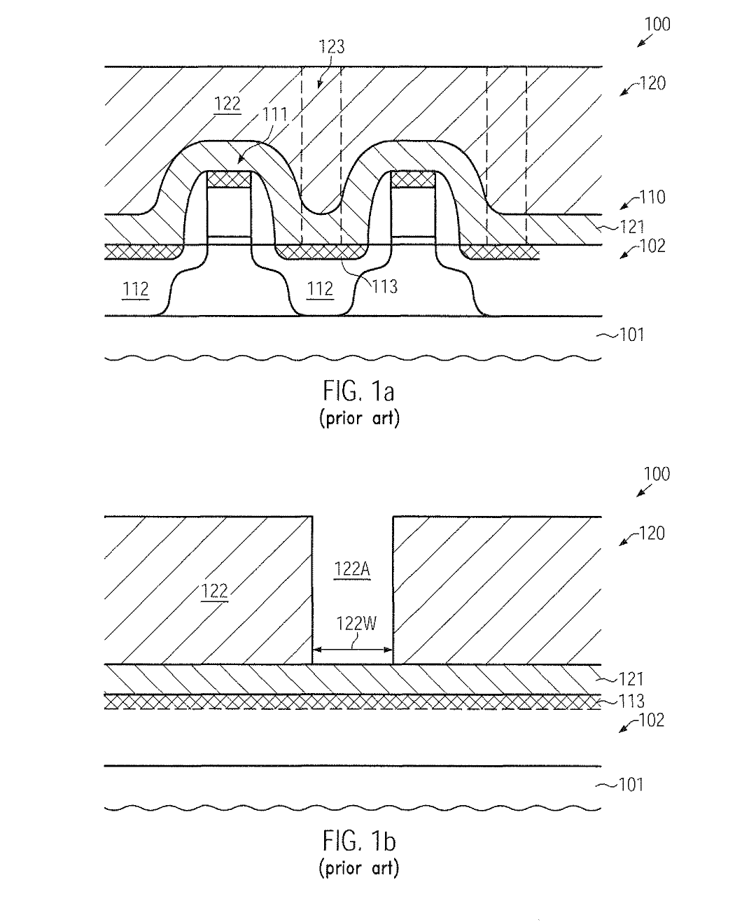

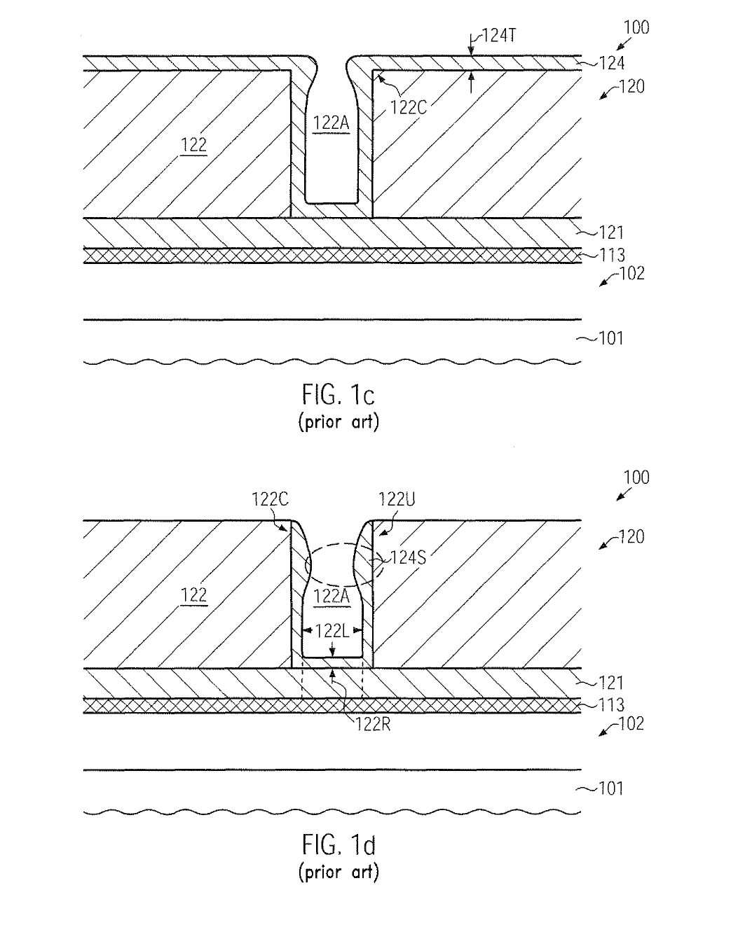

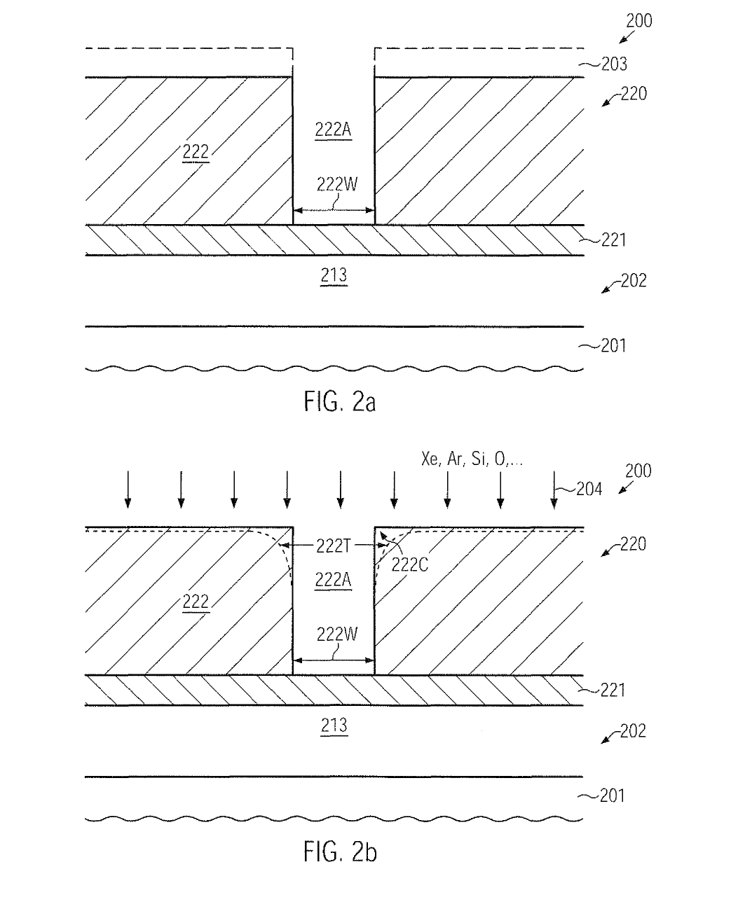

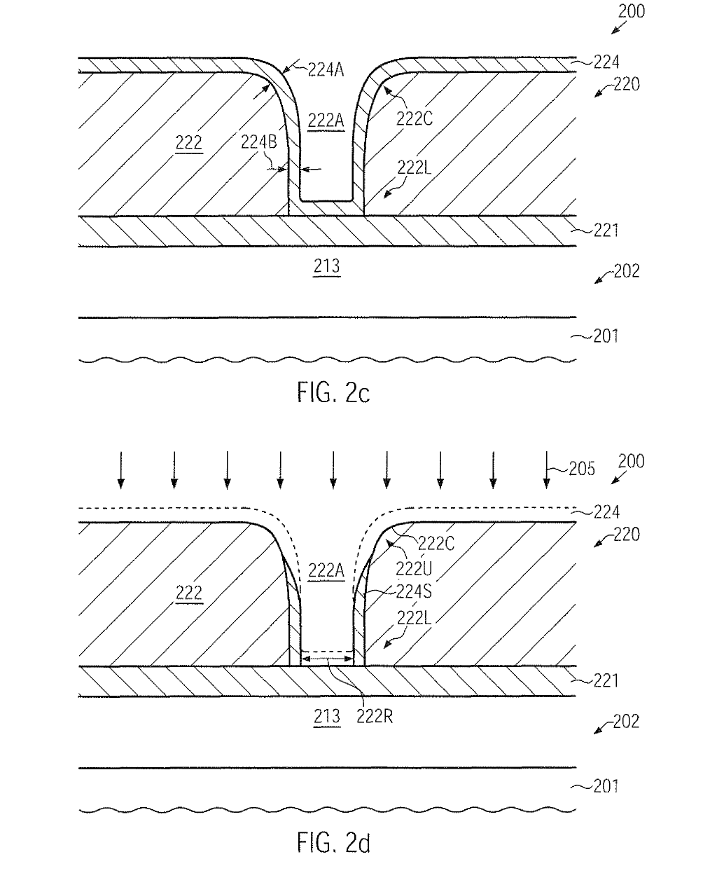

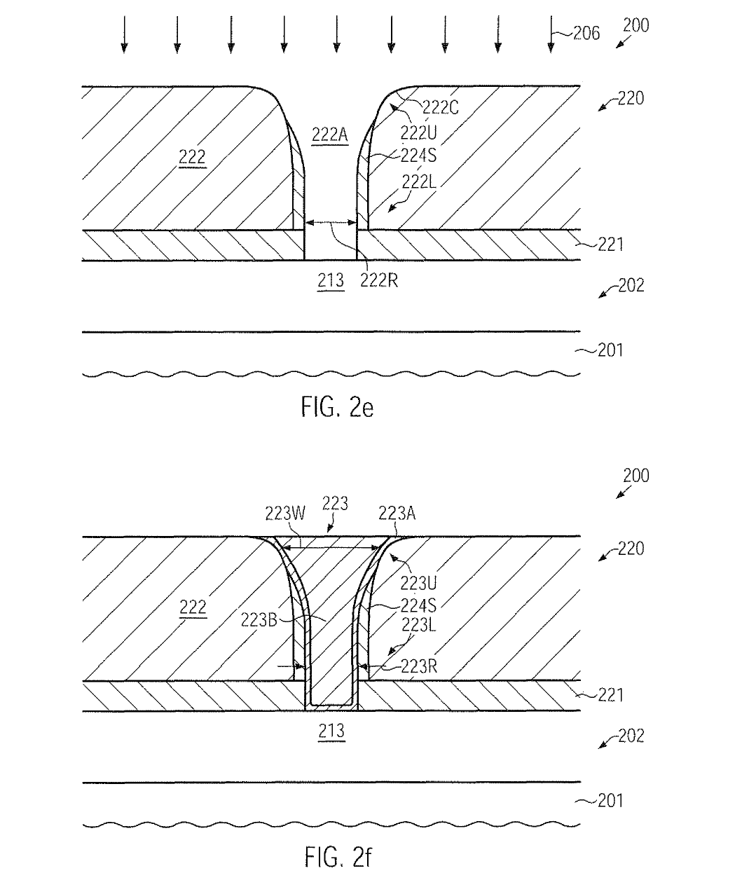

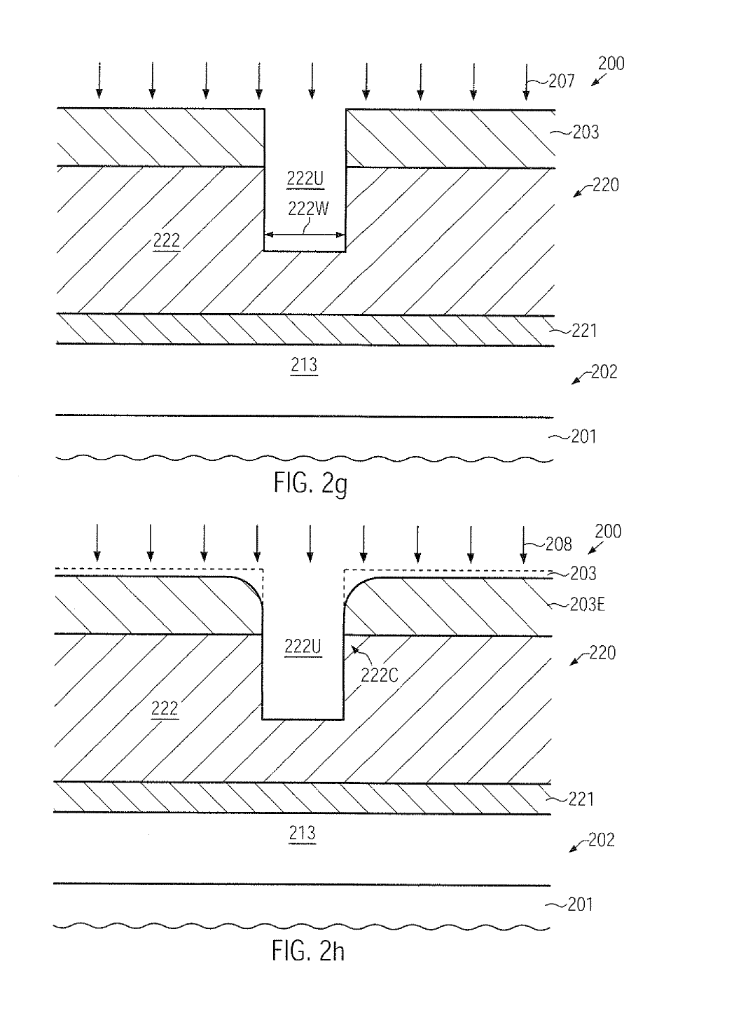

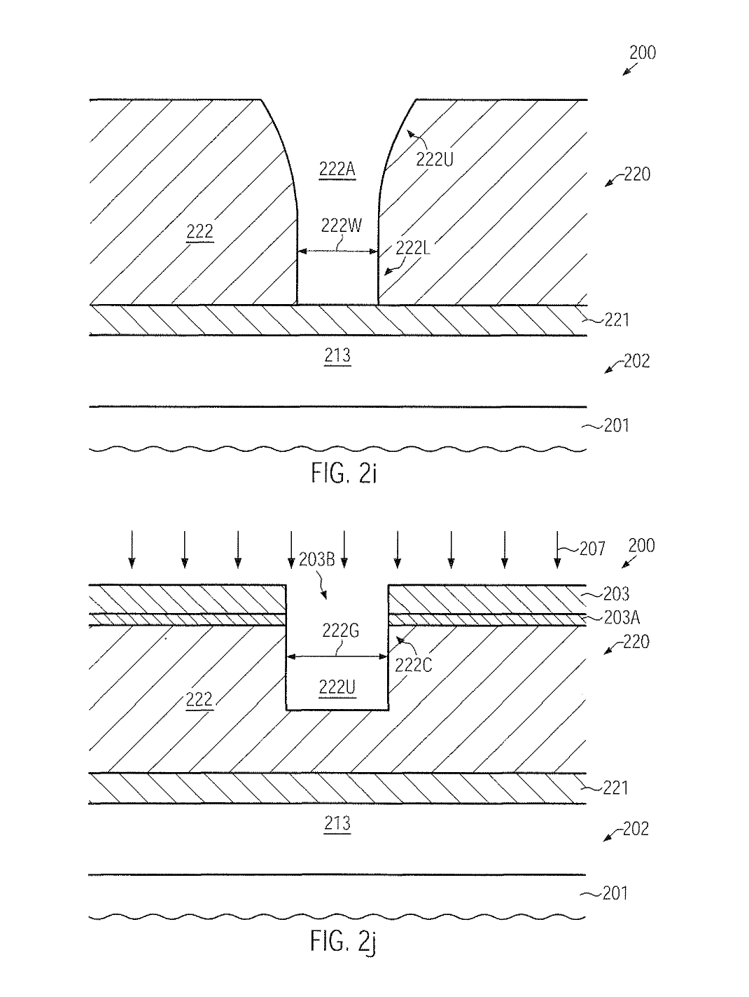

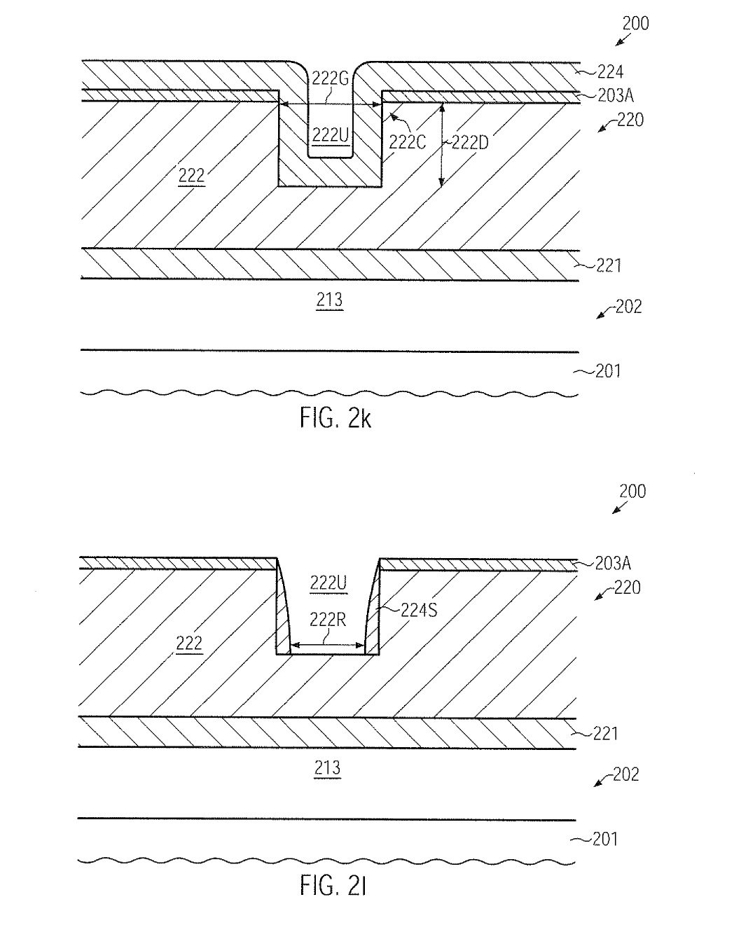

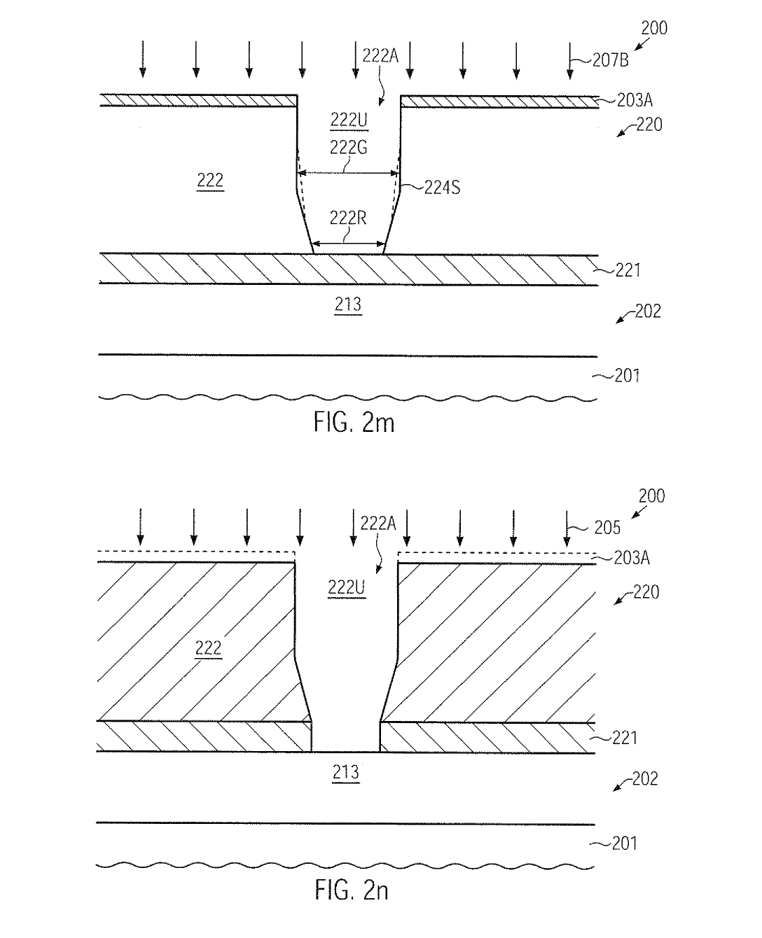

With reference to FIGS. 2a-2n, further illustrative embodiments will now be described in more detail, wherein reference may also be made to FIGS. 1a-1d, if appropriate.

FIG. 2a schematically illustrates a semiconductor device 200 comprising a substrate 201 and a semiconductor layer or region 202. The substrate 201 may represent any appropriate carrier material and the semiconductor layer 202 may be provided in the form of any appropriate semiconductor material, such as silicon, silicon/germanium, germanium, any other semiconductor compounds and the like. Furthermore, the substrate 201 and the semiconductor layer or region 202 may represent an SOI configuration when a buried insulating material (not shown) is formed between the substrate 201 and the semiconductor region 202. In the embodiment shown, the semiconductor region 202 may represent a semiconductor area in which a contact region 213 may be provided that may have any appropriate configuration so as to obtain the desired contact resistivity, as is also previously explained with reference to the device shown in FIG. 1a. For example, the contact region 213 may be comprised of a metal silicide or any other appropriate material composition, while in other cases a semiconductor-based doped material may act as the contact region 213. Moreover, with respect to any other components formed in and above the semiconductor region 202 or the semiconductor layer, the same criteria may apply as previously explained with reference to the device 100. For example, corresponding circuit elements, for instance as previously described, having critical dimensions of 50 nm and less may be formed in and above the semiconductor region 202, thereby defining a corresponding device level. Moreover, the device 200 may comprise a contact level 220 comprising an etch stop material 221, such as a silicon nitride material, a nitrogen-containing silicon carbide material and the like, in combination with an interlayer dielectric material 222, such as a silicon dioxide material and the like. It should be appreciated that the interlayer dielectric material 222 may comprise two or more individual material layers, if considered appropriate for obtaining the desired overall characteristics. Moreover, in the manufacturing stage shown, an etch mask 203 or the residues thereof may still be present above the device level 220. As previously explained with reference to the semiconductor device 100, an etch mask material may comprise a resist material, an ARC material, a hard mask material and the like, as may be appropriate for patterning the interlayer dielectric material 222 so as to form a contact opening 222A therein, which may have an initial target width 222W.

With respect to appropriate process techniques for forming the device 200 as illustrated in FIG. 2a, it may be referred to the description of the conventional device 100. That is, the patterning of the interlayer dielectric material 222 may be accomplished on the basis of sophisticated process strategies, in which the opening 222A may be provided in a reliable and reproducible manner based on the initial target width 222W. After forming the contact opening 222A, the etch mask 203 may be removed, for instance, on the basis of any appropriate plasma assisted removal processes and the like.

FIG. 2b schematically illustrates the device 200 when exposed to a particle bombardment 204, for instance on the basis of ionized or neutral species, such as xenon, argon, krypton, silicon, oxygen and the like. During the particle bombardment 204, a certain degree of material erosion may occur in the dielectric material 222, wherein particularly corner areas 222C may suffer from a significant material removal, thereby causing a certain degree of corner rounding or tapering of the contact opening 222A. For example, the bombardment 204 may be performed as an ion sputter process, which is to be understood as a process for ionizing gas molecules or atoms and accelerating the ionized particles on the basis of an appropriate acceleration system, thereby imparting sufficient kinetic energy to the particles in order to release atoms from a surface layer of exposed portions. In the corner region 222C, the overall material removal may be more pronounced compared to horizontal portions due to an increased surface area that is available for incoming energetic ions or neutral particles. It should be appreciated that a desired degree of corner rounding may be readily obtained by selecting appropriate process parameters, which may be accomplished on the basis of experiments using different bombarding species and energies in combination with the interlayer dielectric material 222 and the specific geometry provided by the contact opening 222A. Consequently, a desired degree of material erosion and thus corner rounding or tapering may be accomplished during the process 204. In other cases, the process 204 may include other surface treatments, such as plasma assisted processes, i.e., the surface of the interlayer dielectric material 222 may be positioned in immediate proximity to a plasma ambient, in order to obtain a certain degree of material erosion, thereby generating the tapering or rounding 222T. Thus, a greater width may be obtained at the top of the contact opening 222A compared to the initial target width 222W.

FIG. 2c schematically illustrates the semiconductor device 200 with a spacer layer 224 formed on the dielectric material 222 and in the contact opening 222A. The spacer layer 224 may be provided in the form of any appropriate dielectric material that may be compatible with requirements for the further processing of the device 200 and in view of electrical performance of the contact level 220. As explained with reference to the device 100, the spacer layer 224 may be provided in the form of a silicon dioxide-based material, which may have similar characteristics compared to the interlayer dielectric material 222. In other cases, any other appropriate dielectric material may be used, as long as it may provide sufficient etch stop capabilities for patterning the etch stop layer 221 on the basis of a desired critical width in a subsequent manufacturing stage. The spacer layer 224 may be deposited by any appropriate deposition technique, such as CVD, possibly as a plasma enhanced process and the like. Due to the superior configuration obtained by the rounded portion 222C, the difference between a thickness 224A at the rounded portion 222C and the thickness 224B at a lower portion 222L may be significantly less pronounced compared to conventional strategies. Consequently, the thickness 224B may be adjusted with superior uniformity, thereby also achieving increased uniformity during the further processing in forming a spacer element and thus defining the desired reduced critical width in the lower portion 222L.

FIG. 2d schematically illustrates the device 200 during an etch process 205 in order to remove material of the spacer layer 224, thereby forming spacer elements 224S at the lower portion 222L, while the material layer 224 may be substantially completely removed from an upper portion 222U, which includes the rounded corner area 222C. The etch process 205 may be formed on the basis of any appropriate isotropic etch recipe, wherein the material 224 may be removed from the upper portion 222U, while also efficiently exposing the etch stop layer 221, since the tapered portion 222U may also provide superior etch conditions within the opening 222A. It should be appreciated that, if desired, the spacer layer 224 may have a different removal rate compared to the dielectric material 222, i.e., a higher removal rate, so that the material 222 may be used as an “etch stop” material. In other illustrative embodiments, the etch process 205 may be performed on the basis of an etch chemistry that may also etch material of the etch stop layer 221, thereby providing a very efficient patterning sequence while nevertheless substantially maintaining a desired reduced width 222R for patterning the etch stop layer 221. For example, the spacer layer 224 may be provided in the form of a silicon nitride material, a nitrogen-containing silicon carbide material and the like when the dielectric characteristics of these materials are considered to be compatible with the overall performance of a contact level 220. In other illustrative embodiments, the spacer layer 224 may be provided on the basis of a low-k dielectric material, which is to be understood as a dielectric material having a dielectric constant of 3.0 or less, which may, therefore, result in a reduced overall permittivity. Furthermore, some low-k dielectric materials may have superior etch stop capabilities, thereby providing a high degree of process uniformity upon patterning the etch stop layer 221 in a subsequent process step. In still other cases, the spacer layer 224 may be provided in the form of a conductive material which may be, due to the superior overall configuration of the contact opening 222A, efficiently removed when forming the spacer elements 224S in the lower portion 222L. For example, titanium, titanium nitride and the like may be efficiently used for the spacer layer 224, while, in other cases, doped polysilicon material and the like may be deposited, if considered appropriate.

FIG. 2e schematically illustrates the semiconductor device 200 in a further advanced manufacturing stage in which a further etch process 206 may be performed on the basis of the contact opening 222A comprising the spacer elements 224S in order to etch through the etch stop material 221. As previously discussed, depending on the material composition of the spacer elements 224S, the etch step 206 may represent one stage of a process sequence for forming the spacer elements 224S and for etching through the material 221. In other cases, the spacers 224S may be used as an etch stop material during the etch process 206 and may thus remain after the process 206 without significant material erosion. It should be appreciated that any well-established etch chemistry may be used for the process 206, such as etch recipes as may also be applied in conventional strategies. It should be appreciated that a more efficient exposure of the etch stop layer 221 may be accomplished due to the superior configuration of the opening 222A, as previously discussed, thereby also providing superior process conditions during the etch step 206.

FIG. 2f schematically illustrates the semiconductor device 200 in a further advanced manufacturing stage. As illustrated, a contact element 223 is formed in the contact level 220, i.e., in the interlayer dielectric material 222 and the etch stop material 221. In the embodiment shown, the contact element 223, which may have any appropriate configuration, such as a “plug-like” configuration, a trench-like configuration and the like, may comprise a conductive metal material 223B, such as tungsten, aluminum, copper and the like, possibly in combination with a conductive barrier material 223A, such as titanium, titanium nitride, tantalum, tantalum nitride and the like. It should be appreciated that, in other cases, any other conductive materials, such as carbon and the like, may also be used, if considered appropriate. Thus, the contact element 223 may comprise an upper portion 223U which may be laterally embedded in the dielectric material 222 and which may have an increased width 223W, which may decrease with increasing depth of the upper portion 223U. On the other hand, the contact element 223 may comprise a lower portion 223L which is to be understood as a portion of the contact element 223 which may directly connect to the spacer element 224S. The lower portion 223L may have a reduced width 223R, when the spacer element 224S is provided in the form of a dielectric material. In other cases, when a conductive material may be used for the spacer element 224S, the reduced dimension 223R may at least be provided in an area that may be laterally embedded in the etch stop material 221.

The contact element 223 may be formed on the basis of any appropriate process sequence which may include the deposition of the barrier material 223A, if required, followed by the deposition of the conductive material 223B, which may be accomplished by sputter deposition, atomic layer deposition (ALD) and the like, for the barrier material 223A, while CVD techniques, electrochemical deposition processes and the like may be applied for forming the material 223B. Irrespective of the deposition techniques applied for depositing the material of the contact elements 223, the superior geometrical configuration may ensure a bottom-to-top fill behavior with a significantly reduced probability of creating irregularities, while nevertheless the reduced width 223R may be maintained.

With reference to FIGS. 2g-2i, further illustrative embodiments will now be described in which a corner rounding may be achieved on the basis of an eroded etch mask.

FIG. 2g schematically illustrates the semiconductor device 200 when exposed to an anisotropic etch process 207 that is performed on the basis of the etch mask 203 in order to form the upper portion 222U in the interlayer dielectric material 222. As previously explained, the etch mask 203 may be patterned so as to obtain the width 222W. At any appropriate stage during the process 207, i.e., after reaching a specific depth in the interlayer dielectric material 222, the etch process 207 may be interrupted in order to intentionally modify the configuration of the etch mask 203.

FIG. 2h schematically illustrates the device 200 during a material erosion process 208 during which material of the etch mask 203 may be removed, thereby providing an eroded etch mask 203E, which may also provide different etch conditions at the corner portion 222C. For this purpose, the process 208 may be performed on the basis of an appropriate plasma ambient in order to promote the removal of material of the etch mask 203, which may be comprised of a resist material and the like. For example, one or more reactive chemicals that may be used during the etch process 207 (FIG. 2g) may be reduced or the supply thereof may be discontinued, while introducing any other appropriate component, such as oxygen and the like, thereby obtaining a certain degree of material erosion. Thereafter, an appropriate etch ambient may be re-established, for instance by using similar process parameters as applied during the process 207 of FIG. 2g, wherein the modified configuration of the etch mask 203E may thus result in an increased material removal at the corner portion 222C.

FIG. 2i schematically illustrates the semiconductor device 200 after the above-described patterning sequence, wherein the upper portion 222U may be broadened or may represent a tapered portion, while the lower portion 222L may be formed substantially on the basis of the width 222W. Consequently, also in this case, a superior configuration of the contact opening 222A may be achieved. Hence, the further processing may be continued on the basis of significantly enhanced overall process conditions, as described above. It should be appreciated that the process 208 of FIG. 2h may be applied twice or more in order to appropriately adjust the degree of tapering in accordance with the overall device requirements. In this case, it may be advantageous to perform the actual etch process for removing the interlayer dielectric material 222 and the process 208 of FIG. 2h as an in situ process sequence.

With reference to FIGS. 2j-2n, further illustrative embodiments will now be described in which the spacer material may be deposited in a portion of the contact opening that has a significantly reduced aspect ratio.

FIG. 2j schematically illustrates the device 200 during the etch process 207, which may be performed on the basis of the etch mask 203, which may include a hard mask material 203A. The etch mask 203 may be patterned so as to provide a mask opening 203B having a width 222G that is selected to achieve appropriate process conditions during the subsequent etching of a spacer material. In some illustrative embodiments, the width 222G may substantially correspond to the width 222W, as previously explained. During the patterning process 207, the hard mask material 203A may be patterned on the basis of, for instance, a resist material which may thus result in superior process conditions for defining the mask opening 203B. Thereafter, the patterning process 207 may be continued by etching into the interlayer dielectric material 222 in order to form the upper portion 222U. It should be appreciated that, in other cases, separate etch processes in separate etch chambers may be applied in order to provide the mask 203 and subsequently perform a patterning process for forming the upper portion 222U. It should be appreciated that the hard mask material 203A may be provided in the form of any appropriate material, such as silicon nitride and the like.

FIG. 2k schematically illustrates the device 200 in a further advanced manufacturing stage. As illustrated, the upper portion 222U may be provided with the width 222G and with a depth 222D which may result in an aspect ratio, i.e., depth to width, that may be significantly less than the aspect ratio defined by the contact opening when extending through the entire interlayer dielectric material 222. Furthermore, the spacer layer 224 may be formed on the hard mask material 203A and within the upper portion 222U. Due to the significantly relaxed deposition conditions, i.e., the reduced aspect ratio, the material 224 may be provided with a reduced degree of overhangs at the corner portion 222C. With respect to any deposition techniques and in view of any material characteristics of the spacer layer 224, it may be referred to the embodiment described above.

FIG. 2l schematically illustrates the device 200 with spacer elements 224S formed within the upper portion 222U. For this purpose, any appropriate anisotropic etch recipe may be applied. Moreover, the hard mask material 203A may act as an efficient etch stop layer, thereby avoiding undue material erosion of the dielectric material 222 outside the opening 222U. In one illustrative embodiment, the spacers 224S may be comprised of substantially the same material as the interlayer dielectric material 222 or may have at least a very similar etch rate compared to the interlayer dielectric material 222. In other cases, the etch rate of the spacer elements 224S may be reduced compared to the removal rate of the interlayer dielectric material 222 with respect to a subsequent anisotropic etch process.

FIG. 2m schematically illustrates the device 200 when exposed to a further anisotropic etch ambient 207B, in which the contact opening 222A may be formed so as to extend to the etch stop layer 221 with a width that may substantially correspond to the reduced width 222R. For example, during the etch process 207B, the material of the spacer elements 224S may be removed, while at the same time the etch front may advance towards the etch stop layer 221 based on the width 222R. On the other hand, undue material removal of the dielectric material 222 may be suppressed due to the presence of the hard mask material 203A, which may thus also provide a well-defined size, i.e., the width 222G. In the embodiment shown, the spacer elements 224S may be substantially completely consumed during the etch process 207B, while in other cases the spacers 224S may remain, however, with a reduced size, thereby also providing the desired increased width 222G in the upper portion 222U while ensuring the desired reduced width 222R at the bottom of the opening 222A. In still other illustrative embodiments (not shown), the spacer elements 224S may be maintained without significant material loss and may be removed in a subsequent process step, for instance when etching through the etch stop material 221.

FIG. 2n schematically illustrates the semiconductor device 200 in a further advanced manufacturing stage in which the etch ambient 205 may be established in order to etch through the etch stop layer 221. This may be accomplished on the basis of any appropriate etch recipes, as previously discussed. Moreover, in some illustrative embodiments, the hard mask layer 203A may also be removed during the etch process 205, for instance when exhibiting a similar removal rate during the process 205 compared to the material of the layer 221. In other cases, the mask material 203A may be maintained and may act as a stop layer during the further processing of the device 200, for instance when filling the contact opening 222A with a conductive material and removing excess material thereof on the basis of chemical mechanical polishing (CMP) and the like.

As a result, the present disclosure provides semiconductor devices and techniques in which critical dimensions of contact openings may be defined on the basis of a spacer material while avoiding or at least reducing the probability of creating a narrow upper portion. For this purpose, the width of the contact opening may be increased or the aspect ratio may be reduced prior to depositing the spacer material, thereby reducing or avoiding a narrowing of an upper portion prior to the further processing. Consequently, due to the superior geometry of the contact openings, the filling in of many conductive materials may be performed on the basis of superior process conditions, thereby reducing the probability of creating contact failures in sophisticated applications.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming a contact element of a semiconductor device, the method comprising:
forming a contact opening in an interlayer dielectric material formed above a semiconductor region that comprises a contact region;
increasing a width of said contact opening at a top area thereof;
forming a spacer element in said contact opening;
performing an etch process through said contact opening so as to etch through an etch stop layer formed between said semiconductor region and said interlayer dielectric material; and
filling said contact opening with a conductive material so as to form said contact element so as to connect to said contact region.

2. The method of claim 1, wherein increasing a width of said contact opening at a top area thereof comprises forming said contact opening on the basis of an etch mask so as to extend to said etch stop layer, removing said etch mask and performing an ion bombardment.

3. The method of claim 1, wherein increasing a width of said contact opening at a top area thereof comprises forming a first portion of said contact opening by using an etch mask, increasing a width of a mask opening of said etch mask and forming a second portion of said contact opening on the basis of said etch mask having the increased mask opening.

4. The method of claim 3, wherein increasing a width of said mask opening comprises performing a plasma treatment so as to erode material of said etch mask.

5. The method of claim 3, wherein increasing a width of said mask opening comprises performing an ion sputter process.

6. The method of claim 3, further comprising further increasing a width of said increased mask opening and forming a third portion of said contact opening on the basis of said further increased mask opening.

7. The method of claim 1, wherein a critical width of said contact opening at a bottom thereof is approximately 50 nm or less.

8. The method of claim 1, wherein increasing a width of said contact opening at a top area thereof comprises performing an ion sputter process.

9. A method of forming a contact element of a semiconductor device, the method comprising:
forming an etch mask above an interlayer dielectric material, said etch mask comprising a hard mask material;
forming a first portion of a contact opening in said interlayer dielectric material on the basis of said etch mask, said first portion terminating in said interlayer dielectric material;
forming a spacer element in said first portion;
forming a second portion of said contact opening on the basis of said spacer element and at least said hard mask material;
performing an etch process so as to etch through an etch stop layer formed below said interlayer dielectric material; and
filling said contact opening with a conductive material.

10. The method of claim 9, wherein forming said etch mask comprises forming a dielectric layer on said interlayer dielectric material and forming a resist material above said dielectric layer.

11. The method of claim 10, wherein said dielectric material comprises silicon and nitrogen.

12. The method of claim 10, wherein performing said etch process comprises removing said hard mask material when etching through said etch stop layer.

13. The method of claim 9, wherein forming said second portion comprises removing material of said spacer element and interlayer dielectric material with a similar removal rate.

14. The method of claim 13, wherein forming said spacer element comprises depositing a dielectric material having substantially the same composition as said interlayer dielectric material.

15. The method of claim 9, wherein said first portion is formed on the basis of a first target width that is selected to comply with deposition capability of a deposition process for forming said conductive material in said contact opening.

16. The method of claim 15, wherein said first portion is formed on the basis of said first target width that is selected to comply with deposition capability of a further deposition process for forming a spacer layer in said first portion.

17. A semiconductor device, comprising:
a contact region formed in a semiconductor region;
an etch stop layer formed on a portion of said contact region;
an interlayer dielectric material formed above said etch stop layer;
a contact element formed in said interlayer dielectric material and said etch stop layer so as to connect to said contact region, said contact element having a tapered upper portion and a substantially non-tapered lower portion, said contact element comprising a conductive material; and
a spacer element selectively formed on sidewalls of said lower portion.

18. The semiconductor device of claim 17, wherein a critical width of said lower portion is approximately 50 nm or less.

19. The semiconductor device of claim 18, wherein a width of said upper portion at a top thereof is greater than said critical width by approximately 20 percent or more.

20. The semiconductor device of claim 17, wherein said conductive material comprises tungsten.
